(19) United States
(12) Patent Application Publication
(10) Pub. No.: US 2014/0367708 A1
(43) Pub. Date: Dec. 18, 2014

(54) LIGHT-EMITTING DIODE ARRANGEMENT

(71) Applicant: OSRAM GmbH, Muenchen (DE)

(72) Inventors: Joerg Sorg, Regensburg (DE); Axel Kaltenbacher, Mintraching (DE); Andreas Biebersdorf, Regensburg (DE)

(21) Appl. No.: 14/363,321

(22) PCT Filed: Dec. 7, 2012
(86) PCT No.: PCT/EP2012/074870

§ 371 Date: Jun. 6, 2014

(30) Foreign Application Priority Data
Dec. 7, 2011 (DE) 10 2011 087 887.4

(51) Int. Cl. H01L 25/075

(52) U.S. Cl. CPC H01L 25/0753; H01L 25/0756
USPC 257/88

(57) ABSTRACT

A light-emitting diode arrangement may include a first layer structure including at least one epitaxially formed light-emitting diode, and at least one second layer structure including at least one epitaxially formed light-emitting diode, wherein the at least one second layer structure is arranged on the first layer structure, and wherein contact faces of the at least one epitaxially formed light-emitting diode in the respective layer structure face contact faces of the at least one epitaxially formed light-emitting diode of the layer structure arranged directly therebelow or thereabove.

### RELATED APPLICATIONS

The present application is a national stage entry according to 35 U.S.C. §371 of PCT application No.: PCT/EP2012/074870 filed on Dec. 7, 2012, which claims priority from German application No.: 102011087887.4 filed on Dec. 7, 2011, and is incorporated herein by reference in its entirety.

### TECHNICAL FIELD

Various embodiments relate to a light-emitting diode arrangement.

### BACKGROUND

These days, conventional lighting means are increasingly displaced commercially by the use of modern lighting means, for example LEDs (light-emitting diodes). By way of example, there are applications, such as the coupling of light into optical waveguides for medical engineering, for which as much light as possible should be produced from the smallest possible area. Conventionally, arc lamps are used for these applications. However, a problem herein is that the arc can move and, moreover, lighting means based on arcs are not very long-lived.

The usability of LED-based illumination means for e.g. the aforementioned applications can be restricted, inter alia as a result of the restricted luminance of the LEDs. In the case of conventionally assumed design rules for printed circuit boards or metal core circuit boards, the distances between the diodes are approximately at least 75 μm. As a result of these boundary conditions, the maximum luminance of an LED light source is therefore usually dominated by the maximum luminance of the LED chip. Since individual chips can only be designed cost-effectively with specific spacings, typically approximately 75 μm to 100 μm in the case of thin-film LEDs or up to approximately 1 mm in the case of sapphire light-emitting diodes, it is expedient to install large chips. However, there are tight limits for this trend. By way of example, these are caused by the fact that wafers have a certain defect density for technological reasons. The sought-after large chips have to be placed on the wafer between the defects. As a result, the usable area on the wafers is greatly reduced. An economically expedient maximum size of the LED chips emerges as a function of the defect density. Currently this boundary lies in the region between 1 mm² and 2 mm².

If even more light is intended to be generated from even smaller areas, the LED-based illumination means currently available reach their technological limits.

### SUMMARY

In various embodiments, a light-emitting diode arrangement is provided, which includes the following: a first layer structure including at least one light-emitting diode, at least one second layer structure including at least one light-emitting diode, wherein the at least one second layer structure is arranged on the first layer structure. Here, further second layer structures can be arranged on the at least one second layer structure. The first layer structure can structurally have the same design as the at least one second layer. The layer structure can be understood to mean an arrangement of diverse material layers, in which light-emitting diodes arranged next to one another are present. Each layer structure can contain filler materials and further functional layers, such as appropriate electric connection or wiring layers, which will be described in more detail below and by means of which the light-emitting diodes can be connected to one another within the respective layer structure. The electric connections within a layer structure can be exposed at the edge of the layer structure for electric contacting purposes such that, for example, respectively one contact is present on two opposite edges of the layer structure.

In accordance with various embodiments of the light-emitting diode arrangement, the first layer structure may include a plurality of light-emitting diodes. The at least one second layer structure may likewise include a plurality of light-emitting diodes. By way of example, the light-emitting diodes in the respective layer structure can be available in a field geometry which, for example, includes LEDs arranged in rows and columns. However, the LEDs can be LED chips or else LED chips provided with a housing or sealed LED chips. If the LEDs are available as LED chips, which can e.g. be formed epitaxially, the thickness of the epitaxy layers, which form the light-emitting diode, can be approximately e.g. 5 μm.

In accordance with various embodiments of the light-emitting diode arrangement, the at least one light-emitting diode or the plurality of light-emitting diodes within the first layer structure and/or within the second layer structure can be arranged on a carrier. The carrier can be translucent or transparent and can e.g. function as a translucent or transparent carrier substrate for the light-emitting diodes arranged thereon, which light-emitting diodes, for example, can also be formed epitaxially on the carrier substrate.

In various embodiments, the term “translucent” or “translucent carrier” (or else “translucent layer” or “translucent material”) can be understood to mean that the carrier is transmissive to light, for example to the light generated by the at least one light-emitting diode of the first layer structure and/or of the at least one second layer structure, for example of one or more wavelength regions, for example to light in a wavelength region of the visible light (e.g. at least in a sub-range of the wavelength range from 380 nm to 780 nm). By way of example, in various embodiments, the term “translucent carrier” should be understood to mean that substantially the whole luminous energy entering the carrier also reemerges therefrom, wherein part of the light can be scattered in the process, as a result of which e.g. a targeted light redistribution can be provided by the carrier such that e.g. the carrier of the layer structure lying over a respective layer structure can be used to set a desired emission characteristic in relation to the light of the layer structure situated therebelow. As a result, it is possible, for example, to set the emission characteristic of the light emitted by the light-emitting diode arrangement.

In various embodiments, the term “transparent” or “transparent layer” (or else “transparent layer” or “transparent material”) can be understood to mean that the carrier is transmissive to light (for example, at least in a sub-range of the wavelength range from 380 nm to 780 nm), wherein light entering into the carrier also reemerges from the carrier substantially without scattering or light conversion. Hence, “transparent” in the various embodiments should be considered to be a special case of “translucent”.

In accordance with various embodiments of the light-emitting diode arrangement, the carrier can be or include a transparent substrate, which has a surface suitable for the growing of epitaxial layers. By way of example, the carrier may include or be a sapphire substrate. Furthermore, the carrier may also include silicon carbide, gallium nitride and/or gallium arsenide. The sapphire substrate can have a thickness in the range from 50 μm to 2 mm, for example in a range from 50 μm to 500 μm, for example in a range from 80 μm to 250 μm, for example in a range from 100 μm to 150 μm. In any case, the sapphire substrate can have a large enough thickness such that, for example, when stacking and adhesively bonding the layer structures, an adhesive used for combining the layer structures does not creep up these. Due to the higher thermal conductivity thereof compared to e.g. conventional silicon substrates, the use of sapphire as a substrate material enables better heat dissipation from the light-emitting diodes.

In accordance with various embodiments of the light-emitting diode arrangement, a spatial region (in other words a volume) between the plurality of light-emitting diodes in the respective layer structure can be filled with a material. By way of example, the spatial region can in each case include regions around the plurality of light-emitting diodes arranged on the carrier and in each case extend as far as the upper edge or the light-emitting surface of the light-emitting diodes. As it were, the material can be considered to be a filling matrix, which can surround the at least one light-emitting diode of the respective layer structure and can fill the otherwise empty spatial regions between the light-emitting diodes of a layer structure in such a way that the latter assumes a plate-like form. The material filled into the spatial region can be translucent or transparent in this case. Furthermore, the material can include a light-converting material, i.e. for example a phosphor which, by means of the fluorescence or phosphorescence mechanism or by means of a mixture thereof, is able to convert, at least in part, the wavelength of the light emitted by the at least one light-emitting diode into light of a different wavelength.

In accordance with various embodiments of the light-emitting diode arrangement, a surface, facing away from the carrier, of the at least one light-emitting diode and the surface of the filled material can form a planar surface in the first layer structure and/or in the at least one second layer structure. In this case, the surface, facing away from the carrier, of the at least one light-emitting diode can be one of the faces through which the light generated by the light-emitting diode leaves the latter.

In accordance with various embodiments of the light-emitting diode arrangement, the light-emitting diode arrangement can have a cuboid structure. Thus, e.g. the individual layer structures, i.e., for example, the first layer structure and the at least one second layer structure, each can have a plate-like form or cuboid form such that they likewise have a cuboid structure overall when arranged one above the other or stacked. Naturally, the number of the individual layer structures in the light-emitting diode arrangement may be three, four, five, six or more.

In accordance with various embodiments of the light-emitting diode arrangement, light emitted by the at least one light-emitting diode of the first layer structure and/or light emitted by the at least one light-emitting diode of the at least one second layer structure can be decoupled on at least one side face of the light-emitting diode arrangement. In the case where the light-emitting diode arrangement has a cuboid form, in principle any one of the side faces can be used for decoupling the light. As mentioned above, the light emission characteristic can also be adapted by means of the carriers such that, for example, the majority of the light emitted by the light-emitting diodes of the light-emitting diode arrangement leaves the latter by means of a forward-facing end face, i.e. substantially perpendicular to each one of the planes of the layer structures. Furthermore, it is also possible for optical elements, such as e.g. lenses, micro lenses, prisms or mirroring elements, to be arranged between the layer structures or in the layer structures and said optical elements can adapt the light path of the light emitted by the at least one light-emitting diode according to requirements. As a result, the light emission characteristic of the light-emitting diode arrangement in accordance with various embodiments can be adapted according to requirements. In general, the light-emitting diode light source in accordance with various embodiments can be used to provide a light-emitting diode light source in which omni-directional light emission is possible.

In accordance with various embodiments of the light-emitting diode arrangement, at least one side face of the light-emitting diode arrangement can be coated with a light-reflecting material. The materials can be inherently conventional, optically reflecting materials, such as silver or aluminum. By attaching a reflecting material onto at least one side face of the light-emitting diode arrangement, the light emission characteristic of the light-emitting diode arrangement can be adapted in a targeted manner. By way of example, mirroring all sidewalls of the light-emitting diode arrangement renders it possible for light to emerge primarily via the end face of the light-emitting diode arrangement, wherein end face of the light-emitting diode arrangement is intended to mean the surface extending parallel to the layer structures. As a result, the luminance of the end face can be maximized.

Furthermore, the carriers can also be included in the optical design of the light-emitting diode arrangement and, for example, can be provided with lens effects such that, in conjunction with reflection coatings, there is a desired luminance and/or a desired light emission characteristic on at least one side face of the light-emitting diode arrangement. Diffuse reflection within the light-emitting diode arrangement can also be achieved by the provision of TiO₂ in silicone.

In accordance with various embodiments of the light-emitting diode arrangement, the plurality of light-emitting diodes of the first layer structure and/or the plurality of light-emitting diodes of the second layer structure can be connected to one another by means of bonding wires.

In accordance with various embodiments of the light-emitting diode arrangement, the plurality of light-emitting diodes of the first layer structure and/or the plurality of light-emitting diodes of the at least one second layer structure can be connected to one another by means of a wiring layer arranged on the planar surface. By way of example, the wiring layer can be embodied as a functional layer after filling the spatial region between the plurality of light-emitting diodes in the respective layer structure with the filling material. Optionally, this can still be preceded by contact faces of the light-emitting diodes being exposed, provided that these are covered by the material.

Alternatively, in accordance with various embodiments of the light-emitting diode arrangement, the plurality of light-emitting diodes of the first layer structure and/or the plurality of light-emitting diodes of the at least one second layer structure can also be connected to one another by means of a wiring layer arranged on the carrier. In this case, the light-emitting diodes of the respective layer structure can be assembled by means of the flip-chip assembly technique, i.e. the light-emitting diode can be assembled directly with the active contacting side or the contact faces thereof facing downward, i.e. toward the carrier or toward the wiring layer arranged on the carrier.

In accordance with various embodiments of the light-emitting diode arrangement, the wiring layer can be embodied as a structured metal layer. A metal layer can be applied first and subsequently be structured in an appropriate manner in order to provide a conductive connection between the light-emitting diodes of the respective layer structure. Here, the contacts or contact faces of the light-emitting diodes can be in contact with the wiring layer. The contacts or contact faces of the light-emitting diodes can include conventional conductive materials, for example a layer sequence made of titanium and copper, titanium copper, copper, silver, aluminum or else combinations of the aforementioned substances. The wiring layer, which in the case of the flip-chip assembly technique is referred to as RDL (redistribution layer), can include conventional materials such as titanium, copper, nickel, aluminum and/or gold. In various embodiments, copper as material is advantageous in that it is a good thermal conductor and, simultaneously, also a good current conductor. By way of example, silver and aluminum can be used if the current-carrying connections or bars are to be reflective since these materials are reflective in the optical wavelength range and, as a result thereof, it is possible e.g. to influence the beam path of the light emitted by the light-emitting diodes. In various embodiments, bars made of silver or aluminum can be protected against corrosion, which can be caused by sulfur or water, by means of (transparent) protective layers.

Furthermore, barrier layers, which prevent migration of metals over the interface between the respective light-emitting diode contact and the wiring layer, can be provided between the contact points of the respective light-emitting diode and the wiring layer. In general, the wiring can be embodied in a front-end manufacturing step or, alternatively, in a back-end manufacturing step. By way of example, in the first case the wiring layer can be formed by vapor deposition of a conductive material such as e.g. gold or silver. Depending on whether the wiring layer is provided on the carrier or on the upper side of the light-emitting diodes, the light-emitting diodes can be formed epitaxially therebefore or thereafter. Forming the wiring layer in a back-end process can be advantageous in that possibly defect light-emitting diodes can be bridged from the outset by virtue of the structuring of the wiring layer being adapted to the yield of the arrangement, i.e. the proportion and/or the distribution of functional light-emitting diodes in the respective arrangement.

In accordance with various embodiments of the light-emitting diode arrangement, the plurality of light-emitting diodes of the first layer structure and/or the plurality of light-emitting diodes of the at least one second layer structure can be interconnected in a series circuit. The light-emitting diodes within the respective layer structure can be available in a grid-like arrangement, i.e., for example, in columns and rows. The electric connection of the light-emitting diodes in the respective layer structure can be brought about by means of the bonding wires, the wiring plane or by means of the layer structure directly adjacent to the light-emitting diodes, as already mentioned above.

In accordance with various embodiments of the light-emitting diode arrangement, the plurality of light-emitting diodes of the respective layer structure can be laterally displaced with respect to one another by half a light-emitting diode structure in relation to the plurality of light-emitting diodes of the layer structure arranged directly therebelow or thereabove.

Moreover, in accordance with various embodiments of the light-emitting diode arrangement, the contacts or contact faces of the at least one light-emitting diode in the respective layer structure can face contact faces of the at least one light-emitting diode of the layer structure arranged directly therebelow or thereabove. By way of example, this may be the case if a wiring layer or bonding wires is/are dispensed with and the electric connection of the light-emitting diodes of the respective layer structure is brought about by means of the light-emitting diodes of the directly adjacent layer structure. The directly adjacent layer structure then may include light-emitting diodes which are offset or displaced laterally, for example by half a light-emitting diode structure, with respect to the light-emitting diodes of the layer structure situated directly therebelow or thereabove. The light-emitting diode contacts of the light-emitting diodes in the two adjacent layer structures can be present facing one another such that, alternatively, respectively one light-emitting diode of the upper and the lower layer structure acts as an electric connection for two light-emitting diodes lying therebelow or thereabove. A contact bridge can be used at the end of a respective light-emitting diode row in order to establish electric contact to another line or row of light-emitting diodes in the respective layer structure. In other words, in accordance with various embodiments, the plurality of light-emitting diodes of the respective layer structure can be connected to one another by means of the plurality of light-emitting diodes of the layer structure situated directly therebelow or thereabove.

In accordance with various embodiments of the light-emitting diode arrangement, the at least one light-emitting diode of the first layer structure and the at least one light-emitting diode of the at least one second layer structure can be interconnected to one another in parallel. There can also be a plurality of light-emitting diodes per layer structure, wherein, for example, groups of light-emitting diodes of respectively one layer structure can be interconnected to one another in parallel.

In accordance with various embodiments of the light-emitting diode arrangement, the at least one light-emitting diode of the first layer structure and the at least one light-emitting diode of the at least one second layer structure can be actuatable independently of one another. There can also be a plurality of light-emitting diodes per layer structure, wherein the light-emitting diodes of the respective layer structure can be actuatable independently of one another.

In accordance with various embodiments of the light-emitting diode arrangement, the at least one light-emitting diode of the first layer structure and the at least one light-emitting diode of the at least one second layer structure can be configured to emit light at wavelengths that differ from one another. Alternatively, the plurality of light-emitting diodes within the respective layer structure can be configured to emit light at wavelengths that differ from one another.

In other words, light-emitting diodes, which emit light at wavelengths that differ from one another, can be arranged in arbitrary combinations within a layer structure and also over away from the various layer structures. By way of example, light-emitting diodes with the same color can be provided on the first layer structure, wherein, however, the wavelength of the emitted light differs from the wavelength of the light emitted by light-emitting diodes which are provided in the at least one second layer structure. However, it is also possible within one layer structure to provide light-emitting diodes which emit light with colors that differ from one another. By providing light-emitting diodes with different colors in the layer structures, it is possible thus to generate any color combinations and/or different color patterns of the light generated by the light-emitting diode arrangement. By way of example, a pixel can be produced in a particularly compact manner in this way.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows, in a cross-sectional view, a light-emitting diode arrangement in accordance with various embodiments;

FIG. 2 shows, in a cross-sectional view, a first layer structure of the light-emitting diode arrangement in accordance with various embodiments;

FIG. 3 shows, in a perspective side view, a first and a second layer structure of a light-emitting diode arrangement in accordance with various embodiments;

FIG. 4 shows, in a perspective side view, a light-emitting diode arrangement, constructed from the first and second layer structure depicted in FIG. 3, in accordance with various embodiments;

FIG. 5 shows a top view of a light-emitting diode arrangement in accordance with various embodiments, including two layer structures; and

FIG. 6 shows, in a perspective side view, a light-emitting diode arrangement including eight layer structures in accordance with various embodiments.

### DETAILED DESCRIPTION

The following detailed description refers to the accompanying drawing that show, by way of illustration, specific details and embodiments in which the disclosure may be practiced.

In the following detailed description, reference is made to the accompanying drawings, which form part of this description and show, for illustration purposes, specific embodiments in which the invention can be implemented. In this regard, direction terminology such as, for instance, “at the top”, “at the bottom”, “at the front”, “at the back”, “front”, “rear”, etc. is used with reference to the orientation of the figure(s) described. Since components of embodiments can be positioned in a number of different orientations, the direction terminology serves for illustration purposes and is not restrictive in any way at all. It goes without saying that other embodiments can be used and structural or logical amendments can be made, without departing from the scope of protection of the present invention. It goes without saying that the features of the different embodiments described herein can be combined with one another, unless specifically indicated otherwise. The following detailed description should therefore not be interpreted in a restrictive sense, and the scope of protection of the present invention is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

In general, the various embodiments can relate to a light-emitting diode arrangement which can have a three-dimensional structure, for example in the form of a light-emitting diode cuboid (or a light-emitting diode cube), in which the light generated by the light-emitting diodes can be decoupled from at least one surface or side of the light-emitting diode cuboid. The surfaces which are not used for decoupling light can be used, for example, for electric contacting and/or for heat dissipation and/or for connecting a temperature management system and/or they can be provided with, or mirrored by means of, e.g. a highly reflective coating.

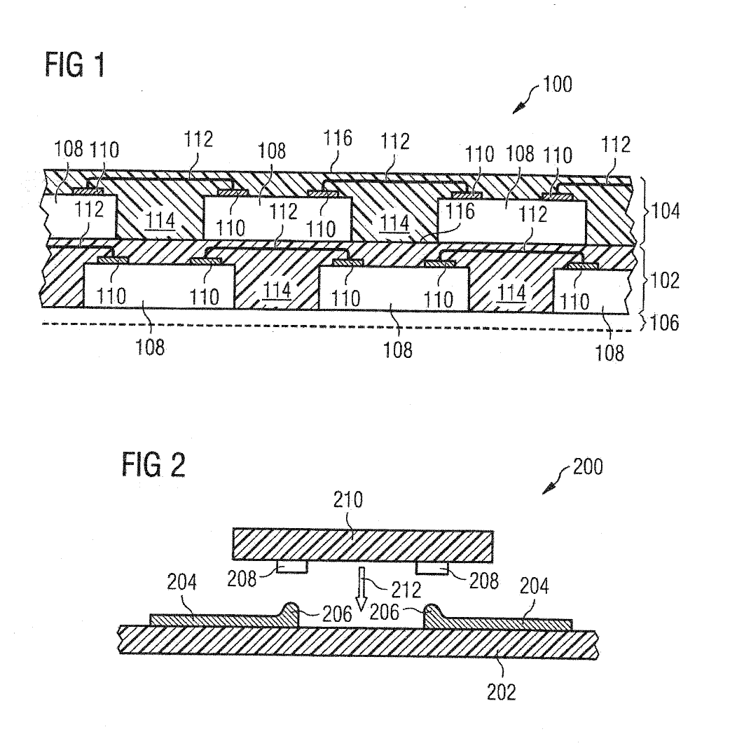

FIG. 1 depicts a light-emitting diode arrangement 100 in accordance with various embodiments. In the depicted example, the light-emitting diode arrangement 100 comprises a first layer structure 102 and a second layer structure 104. The lighting arrangement 100 may naturally include more than the two depicted layer structures, i.e., for example, a first layer structure 102 and two, three, four or a different number of second layer structures 104. Each one of the layer structures includes at least one light-emitting diode 108, for example a Sapphire light-emitting diode. To be more precise, three light-emitting diodes 108 are present in each case per layer structure in the embodiment. Each one of the light-emitting diodes 108 may include two contact faces or contacts 110, which are used for electric contacting. The contacts 110 of the light-emitting diodes 108 within a layer structure, i.e., for example, the three light-emitting diodes 108 of the first layer structure 102 depicted here, by way of example, can be electrically connected to one another by means of bonding wires 112 which can form a contacting plane. Alternatively, use can also be made of a planar metallic wiring layer, for example a structured, planar metal layer, as contacting plane, by means of which the corresponding contacts 110 of the light-emitting diodes 108 of a layer structure can be electrically connected to one another. A spatial region 114 between the light-emitting diodes 108 of the respective layer structure can furthermore be filled with a material, for example a translucent or transparent material such as e.g. silicone, glass, glass-filled silicone, sapphire and/or another translucent or transparent material capable of conducting heat. Additionally, the material provided in the spatial region 114 can also contain, or consist of, light-converting materials and/or light-converting elements. The dimensions or the extent of the spatial region 114 in this case is primarily directed to the distance between the light-emitting diodes 108, which can be adapted according to requirements and/or according to the demanded emission characteristic. In general, the distances between the light-emitting diodes 108 within the respective layer structure may differ, for example with adaptation to the required luminance and light emission characteristic of the light-emitting diode arrangement 100. The material can be filled into the spatial region 114 in such a way that a smooth surface 116, which terminates with the upper edge of the planar contacting plane, is formed. FIG. 1 furthermore shows a holding layer 106, which can be used to form the first layer structure 102. The holding layer 106 may include or be a thermal-release film, on which, first of all, the light-emitting diodes 108 of the first layer structure can be arranged. As an alternative to the thermal-release film, use can also be made of e.g. a Teflon film or a functionally similar surface, from which the first layer structure 102 can be removed again.

After filling the exposed spatial region 114 with the material and forming the contacting plane, the first layer structure 102 is stable enough for e.g. the thermal-release film to be able to be detached by thermal action. When forming the at least one second layer structure 104, it is possible to dispense with the use of a holding layer 106 since the at least one second layer structure 104 can be formed on the surface 116 of the first layer structure 102, for example by virtue of the light-emitting diodes 108 of the at least one second layer structure 104 being adhesively bonded onto the completed first layer structure 102. The at least one second layer structure 104 can substantially have the same design as the first layer structure 102; therefore, the design of the at least one second layer structure 104 is not discussed here in any more detail. However, the at least one second layer structure 104 can have e.g. a different type of wiring plane (i.e., for example, bonding wires 112 or the structured, planar metal layer, as described above) or different distances between the light-emitting diodes 108. Furthermore, there may also still be further layer structures over the one second layer structure 104.

As depicted in FIG. 1, the light-emitting diodes 108 of the two depicted layer structures can be displaced laterally with respect to one another, i.e. arranged in such a way that e.g. the light-emitting diodes 108 of the second layer structure 104 are arranged substantially over regions of the first layer structure 102 in which the filled material is mainly situated.

In the development of the embodiment of the light-emitting diode arrangement 100 depicted in FIG. 1, there can be a change in layer direction of the light-emitting diodes 108 in the respective layer structures. In other words, the contacts 110 of in each case two adjacent layer structures, i.e., for example, the contacts 110 of the light-emitting diodes 108 of the first layer structure 102 and the contacts 110 of the light-emitting diodes 108 of the second layer structure 104, can then be present facing one another. As a result of this, it is possible, for example, to obtain a larger volume within the light-emitting diode device 100 according to various embodiments in which no (absorbing) contact geometry is present.

FIG. 2 depicts an embodiment of a layer structure 200, for example the first layer structure 102 or the second layer structure 104 from FIG. 1. FIG. 2 depicts only a single light-emitting diode 210 since all that should be elucidated here is the principle of a possibility of how the light-emitting diode arrangement 100 depicted in FIG. 1 can be modified.

Instead of arranging a light-emitting diode with the contact sides facing upward, the light-emitting diode can also, as shown in FIG. 2, be arranged with its contact sides 208 facing a carrier 202 by means of the flip-chip assembly technique. FIG. 2 depicts the light-emitting diode 210 before attachment to the carrier 202. A wiring layer 204, by means of which the light-emitting diodes of one layer structure can be connected to one another electrically, can be provided on the carrier 202. After attaching the light-emitting diode 210 on the carrier 202, a fixed connection is provided between the contacts 208 of the light-emitting diode and bumps (lower contacts) 206 of the wiring layer 204.

Proceeding from the approach depicted in FIG. 2, it is therefore possible to construct a light-emitting diode device in accordance with various embodiments by virtue of flip-chip light-emitting diodes being applied in a tight grid onto a planar contacting wiring (e.g. RDL) 204 which can be situated on the carrier 202. A layer structure 200 produced thus can then by stacking be used to construct a light-emitting diode device analogous to the light-emitting diode device 100 depicted in FIG. 1.

By way of example, the light-emitting diode 210 can be applied onto the carrier 202 by means of thermosonic bonding. To this end, the light-emitting diode 210 can comprise stud bumps or other bumps (such as e.g. bumps produced by plating) on the contact points 208 thereof. However, alternatively, the bumps can also be produced on the contacting plane, i.e. on the wiring layer 204, as depicted in FIG. 2. To this end, bumps can be grown onto the planar redistribution layer (RDL) 204 at the contacting points by means of plating methods, onto which bumps the light-emitting diode chip 210 can then be bonded directly.

That is to say, a placement head, which holds the light-emitting diode chip 210 during assembly, can exert force and ultrasound in the direction of an arrow 212 depicted in FIG. 2 and can thereby form a frictional connection between the contact faces or contacts 208 of a light-emitting diode 210 and the respective bumps 206. In the process, the redistribution layer 204 of the first layer structure can be situated on a transparent carrier 202 or a temporary carrier which can be removed after completion of the first layer structure.

After applying the light-emitting diodes, for example sapphire light-emitting diodes, onto the carrier 202 of the first layer structure 200 by means of the flip-chip assembly technique, the gaps or the spatial region between the light-emitting diodes (to the extent that these are/this is present) can be filled with the translucent or transparent material in order to produce a planar surface. On the rear-side surface, i.e. the surface of the light-emitting diodes 210 facing away from the carrier 202, of the light-emitting diodes, it is now possible, once again, to plate a planar redistribution layer and optionally bumps thereon or to produce stud bumps. This makes it possible to produce a three-dimensional light-emitting diode structure, for example a flip-chip sapphire light-emitting diode cube or cuboid, by stacking layer structures.

The contacts 208 of the respective light-emitting diode 210 can be guided laterally as far as an edge of the light-emitting diode chip or of the light-emitting diode and can subsequently be rewired by means of conductive structures which can be formed by sputtering and photo-technology.

In accordance with various embodiments of the light-emitting diode arrangement, the latter can also be constructed by stacking of layer structures, wherein the layer structures can comprise, respectively alternately, light-emitting diodes with the contacts arranged upward and light-emitting diodes with the contacts arranged downward, for example flip-chip light-emitting diodes. Thus, for example, the first layer structure can correspond to the first layer structure 102 from FIG. 1; the at least one second layer structure can correspond to a layer structure 200 constructed in accordance with FIG. 2. Therefore, in such an arrangement, the contacts from the one layer, for example the first layer structure, are facing the contacts from the second layer, for example the at least one second layer structure. The light-emitting diodes of the one layer structure can, in this case too, be displaced with respect to the light-emitting diodes of the other layer structure by half a light-emitting diode structure, as a result of which, for example, the at least one second layer structure can then be used to provide electric bridge contacts between the light-emitting diodes of the first layer structure. Naturally, conversely, the light-emitting diodes of the first layer structure then form electric bridge contacts for the light-emitting diodes of the at least one second layer structure. Further pairs made of in each case two layer structures with contacts facing one another can be arranged on the two layer structures just described above.

In accordance with further embodiments of the light-emitting diode arrangement, the layer structure can also be produced by virtue of an epitaxy layer being formed on a transparent carrier or carrier substrate. The carrier which can also be embodied as a wafer may, for example, include, or consist of, glass or sapphire. In accordance with various embodiments, a wafer or substrate can be understood to mean a material base on which a layer can be formed epitaxially. The layer formed by epitaxy can subsequently be detached from the substrate and be applied, for example by adhesive bonding, to a different material base, for example a carrier. The substrate can be or include a monocrystalline material, while the carrier can be polycrystalline or amorphous. The redistribution layer can be formed on the whole carrier prior to the epitaxial formation of the light-emitting diodes. If the carrier is embodied as a wafer, the redistribution layer can be formed at the wafer level during the production of the layer structure. In the case of a carrier which is not a wafer, the redistribution layer can be formed individually in each case on the surface on which the light-emitting diodes are then formed, wherein the rewiring can reach up to an edge or a border of the carrier. The redistribution layer can be available in the form of a planar, structured metal layer. Layer structures produced thus can then be stacked one above the other (analogously to the light-emitting diode arrangement 100 shown in FIG. 1) and can be put together by means of an adhesive, for example a translucent or transparent glue. If the redistribution layer does not reach to the edge of the carrier after the layer structure was produced, contacts can be exposed e.g. by sawing.

Alternatively, use can also be made of a laser to provide openings in the side faces of the respective layer structure where the redistribution layer is not yet exposed but where contact points for contacting the wiring layer from the outside are desired. The individual layer structures in the stack of layer structures forming the light-emitting diode arrangement can therefore be electrically contacted by means of edge contacts of the respective layer structure. Alternatively, use can also be made of through contacts in the wafers in order to electrically contact the respective layer structures.

Further embodiments of the light-emitting diode device may include epitaxy layers on translucent or transparent films. In order to form a layer structure, the light-emitting diodes can in this case be arranged on, or embedded in, a thin, flexible material layer or film, which can be translucent or transparent. The thin-layer films can then be laminated onto one another in order to obtain a solid body.

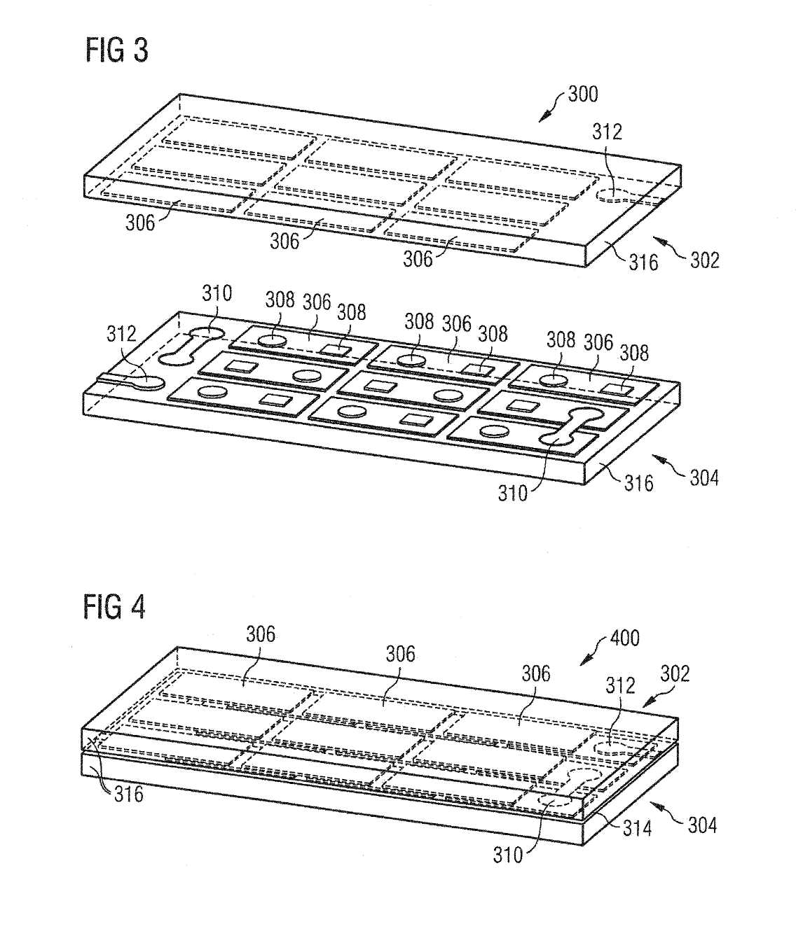

FIG. 3 depicts, in a perspective side view, a first layer structure 304 and a second layer structure 302 of a light-emitting diode arrangement 300 in accordance with various embodiments. In this illustration, the two layer structures are depicted separately from one another for elucidation purposes.

FIG. 4 shows the same layer structures as in FIG. 3, but these are depicted in an assembled state in FIG. 4. It is stressed once again that despite the literal delimitation between the first and the (at least one) second layer structure, it is not mandatory for there to be a difference between these; here, these can be layer structures constructed in the functionally same manner. Conventionally, the production of the light-emitting diode arrangement in accordance with various embodiments can start with the first layer structure.

Both the first layer structure 302 and the at least one second layer structure 304 in FIG. 3 can be wafers or wafer segments with light-emitting diodes 306 formed thereon, which wafers or wafer segments can be assembled to form three-dimensional structures in the form of layer-structure stacks. In the embodiment described here, two substrates with light-emitting diodes formed epitaxially thereon can in each case be assembled directly as wafer segments, wherein the surfaces of said substrates face one another. As a result, it is possible to dispense with adhesively bonding and separating the light-emitting diode chips. Alternatively, the wafer segments can be “artificial wafers”, i.e. segments which are assembled from individual light-emitting diodes, which have for example been adhesively bonded to one another. In the embodiment of the light-emitting diode arrangement 300 depicted in FIG. 3, nine light-emitting diodes 306, in three lines (columns) with in each case three light-emitting diodes 306 per row (line), are arranged on each wafer 316, which serves as a carrier. This arrangement constitutes one of many possibilities of how the light-emitting diodes 306 can be arranged on a wafer or wafer segment 316 and should not be construed as being restrictive. Each light-emitting diode 306 has two contacts 308, by means of which they can be supplied with current. The three lines of in each case three light-emitting diodes 306 of the first layer structure 304 and of the second layer structure 302 are displaced or offset with respect to one another by half a light-emitting diode structure such that, when assembling the two layer structures, it is possible to dispense with a wiring plane since the three light-emitting diodes 306, respectively arranged in one line, of the first layer structure 305 can be connected to one another by means of the three light-emitting diodes 306, respectively arranged in one line, of the second a layer structure 302 (and vice versa). In this embodiment, all light-emitting diodes 306 of a layer structure are interconnected in a series circuit. In order to get from one line to the next at the edge of a layer structure, a bridge contact 310 can be arranged there. Expressed differently, the bridge contacts 310 can be used to close the circuit of the light-emitting diodes 306. Furthermore, external contacts 312 can be provided at the edge of the layer structure such that the layer structure can be electrically contacted from the outside. These can be embodied as bridge contacts guided laterally to the outside. The bridge contacts 310 and the external contacts 312 can comprise conventional metallic materials which conduct current well, such as copper, aluminum, silver, nickel, gold or any alloys thereof. By assembling or joining together the first layer structure 302 and the second layer structure 304 to form the structure shown in FIG. 4, empty interspaces are created around the light-emitting diodes 306 due to the fact that the epitaxy layer forming the light-emitting diodes 306 can usually have a thickness of approximately 5 μm. Furthermore, the contacts 308 can have a thickness in the range from 5 μm to 10 μm. The distance between the surfaces, facing one another, of the carriers 316, i.e. a maximum height of the spatial region or the interspace, can lie in a region from a few micrometers to 100 μm, for example in a region from approximately 10 μm to approximately 40 μm. The interspaces form an empty spatial region which can be filled with the translucent or transparent material 314 capable of thermal conduction. The filling material 314 can increase the cohesion of the two layer structures. Furthermore, the material can be provided with transparent fillers such as SiO₂, Al₂O₃ or other materials, the refractive index of which lies approximately in the region of the substrate 316 and of the filling material 314, in order to improve the thermal conduction capability and reduce the CTE (coefficient of thermal expansion) mismatch (discrepancy) between the filling material 314 and the epitaxially formed light-emitting diodes 306. In order to increase the heat dissipation, the filling material 314 can also be porous in order to enable a through-flow of a fluid such that, effectively, a translucent or transparent cooling fluid, for example silicone oil, can flow through the spatial region so that more heat can be dissipated from the light-emitting diodes 306. However, a channel system can also be provided in a targeted manner in the spatial region, or through the interspaces, through which channel system a cooling fluid may flow. Furthermore, light-converting layers can be provided in the interspaces and/or over the surfaces, not covered by contacts 308, of the light-emitting diodes 306.

FIG. 5 elucidates the principle of interconnecting the light-emitting diodes 306 in the assembled layer-structure pair, depicted in FIG. 4, which can form a light-emitting diode device 500 in accordance with various embodiments. An electric connection 502 by means of the light-emitting diode, lying thereabove, of the second layer structure is provided between respectively two adjacent light-emitting diodes 306 in each line of the first layer structure 304. As a result, the contact face which does not transmit light can be reduced to a minimum and a particularly compact arrangement of the light-emitting diodes 306 can be achieved in the light-emitting diode arrangement 500. The series circuit of the light-emitting diodes 306 can be supplied with power by means of the external contacts 312.

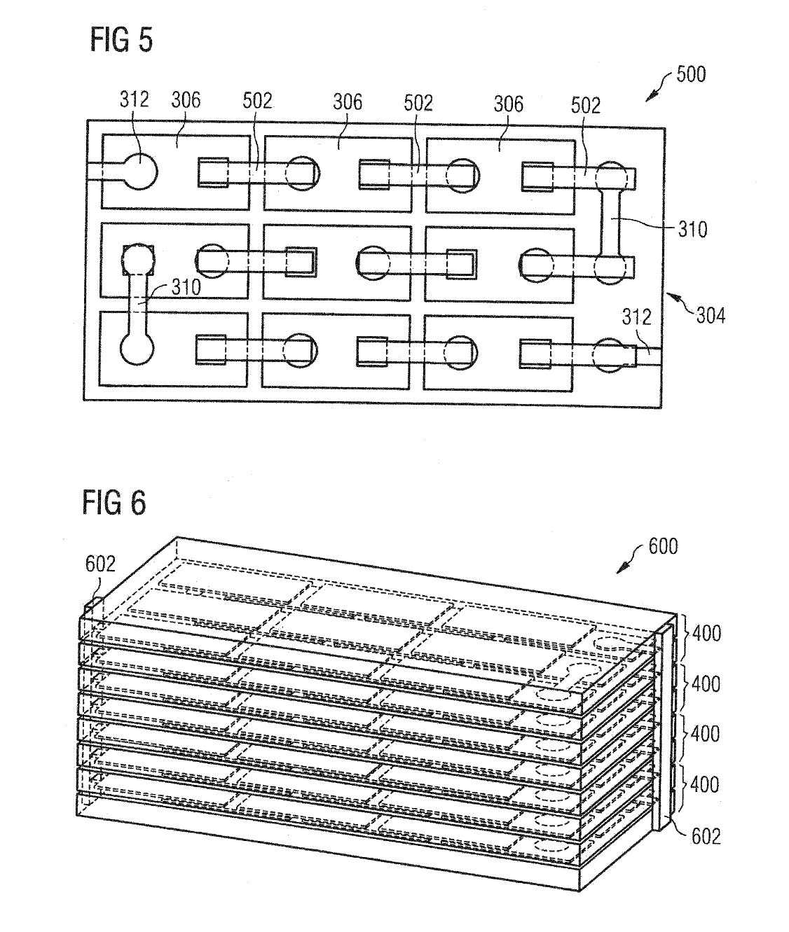

A further embodiment of a light-emitting diode arrangement 600 is depicted in FIG. 6. The light-emitting diode arrangement 600 can be assembled from a plurality of structures 400 in accordance with FIG. 3 and FIG. 4. In the given example, four pairs of layer structures 400 are assembled or stacked above one another. The light-emitting diodes can respectively be interconnected in series in each pair of layer structures, as already explained in FIG. 5. Power lines 602, which are electrically connected to the respective external contacts of the layer structures, can be arranged on the sides of the light-emitting diode arrangement 600. In this embodiment, the six layer structures are all interconnected in parallel.

By stacking layer structures above one another, it is thus possible to combine many epitaxy plies, which form light-emitting diode chips or light-emitting diodes, to form a light source in a very restricted space. An expedient number of layer structures in a light-emitting diode arrangement in accordance with various embodiments is determined e.g. by the transparency of the carriers (substrates), of the epitaxy-ply layer and/or by the internal reflection losses at the contacts or contact faces.

By way of example, using the described light-emitting diode arrangement in accordance with various embodiments, it is possible to provide three-dimensional pixels for display applications. Thus, a pixel can have three layer structures, wherein a light-emitting diode with a different primary color can be arranged on each structure; that is to say, for example a green light-emitting diode on the first layer structure, a blue light-emitting diode on the second layer structure and a red light-emitting diode on the third layer structure. Any color combinations can be generated upon individual actuation of the three layer structures. By stacking the three light-emitting diodes on one another, it is possible to form a particularly compact pixel unit. With the aid of the light-emitting diode arrangement, of which some embodiments were highlighted above, it is possible to obtain values of the luminance which lie significantly above the luminance of the individual light-emitting diode (light-emitting diode chip). Here, obtaining a higher luminance is based on the basic concept that a larger luminous energy can be generated in a volume than in a surface. By arranging light-emitting diodes in a three-dimensional structure, it is therefore possible to exceed the previously conventionally reached quotient of maximum luminous energy per unit area since the luminous energy can be emitted over an area, but can be produced in the volume. As a result, it is possible to create light-emitting diode arrangements in which the luminance of the light-emitting diode (chip) surface is significantly exceeded. Furthermore, a light-emitting diode light source can be provided with the light-emitting diode arrangement in accordance with various embodiments, in which the light emission is omni-directional.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A light-emitting diode arrangement, comprising:
a first layer structure comprising at least one epitaxially formed light-emitting diode, and
at least one second layer structure comprising at least one epitaxially formed light-emitting diode,
wherein the at least one second layer structure is arranged on the first layer structure, and
wherein contact faces of the at least one epitaxially formed light-emitting diode in the respective layer structure face contact faces of the at least one epitaxially formed light-emitting diode of the layer structure arranged directly therebelow or thereabove.

2. The light-emitting diode arrangement as claimed in claim 1,
wherein the first layer structure comprises a plurality of epitaxially formed light-emitting diodes.

3. The light-emitting diode arrangement as claimed in claim 1,
wherein the at least one second layer structure comprises a plurality of epitaxially formed light-emitting diodes.

4. The light-emitting diode arrangement as claimed in claim 2,
wherein the plurality of epitaxially formed light-emitting diodes within the first layer structure is arranged on a translucent carrier.

5. The light-emitting diode arrangement as claimed in claim 2,
wherein the plurality of epitaxially formed light-emitting diodes within the first layer structure is arranged on a transparent carrier.

6. The light-emitting diode arrangement as claimed in claim 4,
wherein the carrier is a transparent substrate, which has a surface suitable for the growing of epitaxial layers.

7. The light-emitting diode arrangement as claimed in claim 2,
wherein a spatial region between the plurality of epitaxially formed light-emitting diodes in the first layer structure is filled with a material.

8. The light-emitting diode arrangement as claimed in claim 1,
configured in such a way that light emitted by the at least one epitaxially formed light-emitting diode of the first layer structure and/or light emitted by the at least one epitaxially formed light-emitting diode of the at least one second layer structure is decoupled on at least one side face of the light-emitting diode arrangement.

9. The light-emitting diode arrangement as claimed in claim 1,
wherein at least one side face of the light-emitting diode arrangement is coated with a light-reflecting material.

10. The light-emitting diode arrangement as claimed in claim 2,
wherein the plurality of epitaxially formed light-emitting diodes of the first layer structure is interconnected in a series circuit.

11. The light-emitting diode arrangement as claimed in claim 1,
wherein the plurality of epitaxially formed light-emitting diodes of the respective layer structure are connected to one another by means of the plurality of epitaxially formed light-emitting diodes of the layer structure situated directly therebelow or thereabove.

12. The light-emitting diode arrangement as claimed in claim 3,
wherein the plurality of epitaxially formed light-emitting diodes within the second layer structure is arranged on a translucent carrier.

13. The light-emitting diode arrangement as claimed in claim 3,
wherein the plurality of epitaxially formed light-emitting diodes within the second layer structure is arranged on a transparent carrier.

14. The light-emitting diode arrangement as claimed in claim 5,
wherein the carrier is a transparent substrate, which has a surface suitable for the growing of epitaxial layers.

15. The light-emitting diode arrangement as claimed in claim 12,
wherein the carrier is a transparent substrate, which has a surface suitable for the growing of epitaxial layers.

16. The light-emitting diode arrangement as claimed in claim 13,
wherein the carrier is a transparent substrate, which has a surface suitable for the growing of epitaxial layers.

17. The light-emitting diode arrangement as claimed in claim 3,
wherein a spatial region between the plurality of epitaxially formed light-emitting diodes in the at least one second layer structure is filled with a material.

18. The light-emitting diode arrangement as claimed in claim 3,
wherein the plurality of epitaxially formed light-emitting diodes of the at least one second layer structure is interconnected in a series circuit.
